(19) United States
(12) Patent Application Publication
(10) Pub. No.: US 2026/0126614 A1
(43) Pub. Date: May 7, 2026

(54) OPTICAL MODULE AND PROJECTION EXPOSURE SYSTEM

(71) Applicant: Carl Zeiss SMT GmbH, Oberkochen (DE)

(72) Inventors: Jens KUGLER, Aalen (DE); Andreas RABA, Niederschoenefeld (DE); Marwene NEFZI, Aachen (DE)

(21) Appl. No.: 19/426,779

(22) Filed: Dec. 19, 2025

Related U.S. Application Data
(63) Continuation of application No. PCT/EP2024/067969, filed on Jun. 26, 2024.

(30) Foreign Application Priority Data
Jun. 27, 2023 (DE) 10 2023 116 895.9
Jun. 27, 2023 (DE) 10 2023 116 899.1

(51) Int. Cl. G02B 7/18; G02B 7/182; G03F 7/00

(52) U.S. Cl. CPC G02B 7/1815; G02B 7/182; G03F 7/70266; G03F 7/70316; G03F 7/70825; G03F 7/7085; G03F 7/70891; G03F 7/70958

(57) ABSTRACT

An optical module comprises an optical element and a stiffening body. The optical element comprises an optical effective surface. The optical element is connected to the stiffening body by way of a connection element. The connection element comprises a decoupling region which mechanically decouples the stiffening body and the optical element parallel to the optical effective surface.

### CROSS-REFERENCE TO RELATED APPLICATION

The present application is a continuation of, and claims benefit under 35 USC 120 to, international application No. PCT/EP2024/067969, filed Jun. 26, 2024, which claims benefit under 35 USC 119 of German Application Nos. 10 2023 116 895.9 and 10 2023 116 899.1, filed on Jun. 27, 2023. The entire disclosure of each of these applications is incorporated by reference herein.

### FIELD

The disclosure relates to an optical module for a projection exposure apparatus and to a projection exposure apparatus for semiconductor lithography.

### BACKGROUND

Projection exposure apparatuses for semiconductor lithography are used for producing extremely fine structures, for example on semiconductor components or other microstructured components. An idea of the apparatuses involves the production of extremely fine structures down to the nanometer range by way of generally reducing imaging of structures on a mask, a so-called reticle, on an element to be structured, such as, for example, a wafer, that is provided with photosensitive material. The minimum dimensions of the structures produced depend on the resolution of the optical system used for imaging.

The resolution, in turn, in general depends directly on the wavelength of the radiation used for imaging, which is known as the used radiation, and the numerical aperture, i.e. the product of the refractive index of the surrounding medium and the opening angle of the optical system used for imaging. Light sources that produce radiation in an emission wavelength range from 100 nm to 300 nm, referred to as the DUV range, are used to produce the used radiation, wherein light sources with an emission wavelength in the order of a few nanometers, for example between 1 nm and 120 nm, for example in the order of 13.5 nm, have found increased use in recent times. The emission wavelength range described last is also referred to as the EUV range.

In the optical system, optical elements such as lens elements and mirrors are used to illuminate the structures and for example to image them, wherein mirrors are usually used in the field of EUV lithography on account of the strong absorption of the emission wavelengths used therein by most materials. In order to image the structures, so-called optical effective surfaces of the optical elements are exposed to used radiation. Within the scope of imaging, deviations of the position of the optical elements from an optimum target position typically have a relatively large influence on the quality of image representation and hence on the quality of the components produced. To help meet the stringent desire properties in relation to position, the position of a predominant number of mirrors can be actively controlled. Such closed-loop control typically involves a high control bandwidth, which depends inter alia on the first internal natural frequencies of the optical element or optical module, wherein the lowest internal natural frequency should be above 1500 Hz. Lower natural frequencies can lead to the sensors for the closed-loop control starting to vibrate in the low-frequency range (<1500 Hz), whereby rigid body control for positioning the mirror may become unstable. In addition to the optical element, an optical module additionally comprises at least the actuators and sensors for positioning purposes and the connection thereof to the optical element.

The desired natural frequencies, which as shown above are relatively high, involve the use of a certain amount of comparatively expensive materials in order to attain the desired stiffness, especially in view of the main bodies, for example the main bodies of mirrors. In view of this issue, proposals have been made in the past to arrange comparatively thin optical elements on stiffening bodies made of comparatively stiff materials, with these stiff materials not needing to be the relatively expensive known materials of the main bodies of optical elements. However, a challenge remains in view of compensating the deviations between the respective coefficients of thermal expansion of the elements involved, as these are quite significant in this case.

### SUMMARY

The present disclosure seeks to provide an optical module, in which an optical element is arranged on a separate stiffening body and wherein the issue of different coefficients of thermal expansion is effectively counteracted.

In an aspect, the disclosure provides an optical module comprising an optical element and a stiffening body, with the optical element comprising an optical effective surface. In this case, the optical element can be connected to the stiffening body by way of at least one connection element. According to the disclosure, the connection element can comprise a decoupling region which provides mechanical decoupling of the stiffening body and the optical element parallel to the optical effective surface.

Within the meaning of the disclosure, decoupling means the reduction of the transmission of forces and/or moments and/or stresses between the optical element and the stiffening body. As a result, a lateral deformation of the stiffening body on account of temperature changes does not lead, or only leads to a reduced extent, to the introduction of undesirable forces and/or moments into the optical element. A potential lateral deformation of the stiffening body and/or of the optical element can cause a displacement of the contact points of the connection elements on the stiffening body and on the optical element, with this displacement depending on the distance of the temperature-invariant fixed point of the stiffening body or optical element. As a result of decoupling, the displacements may not lead to a deformation of the optical effective surface that is decisive for the imaging quality, or any such resultant deformation is only minor. In this case, decoupling may be realized actively, i.e. by the displacement of an actuator, for example, and/or passively, i.e. by a spring and/or a kinematic mechanism.

In a first embodiment, the at least one connection element may be arranged between the optical element and the stiffening body in the direction of an optical axis of the optical module. Especially in the case of an optical element in the form of a mirror, an arrangement on the back side of the mirror can be comparatively simple on account of the sufficient amount of available installation space.

For example, the at least one connection element may take the form of an actuator such that the connection element can be deflected in at least one direction.

In an embodiment, the actuator may comprise at least one region which is deflectable parallel to the optical effective surface. As a result, as explained above, it is possible to bring about decoupling between the optical element and the stiffening body in the event of a displacement of the contact surfaces of the connection elements on the stiffening body and on the optical element, the displacement being caused by a potential lateral deformation of the stiffening body and/or optical element. This applies for example to the decoupling of the displacements of the contact surfaces of the connection elements that occur during the operation of the projection exposure apparatus as a result of temperature changes in the optical element and/or in the stiffening body. The region may also serve to compensate for manufacturing and/or assembly tolerances that occur in the direction of the optical effective surface. For example, the actuator may comprise at least two regions which are deflectable perpendicular to each other and parallel to the optical effective surface. This allows displacements within the xy-plane formed parallel to the optical effective surface to be corrected, with the value of the displacement depending on the distance of the respective contact surfaces from a temperature-invariant fixed point of the stiffening body or optical element.

Furthermore, the at least one region can be actively controllable. An actively controllable region means that, in addition to a one-time compensation of manufacturing and/or assembly tolerances during the production of the optical module, the connection element can still be adapted even during operation. As a result of the active region, the thermally induced displacements of the contact surfaces by the actuator may likewise be actively decoupled by a deflection parallel to the optical effective surface.

In an embodiment, the actuator may comprise at least one region which is deflectable perpendicular to the optical effective surface. As a result, depending on which region or regions are active, the connection element can also be used to set the position and/or the predetermined surface geometry of the optical effective surface relevant to the imaging.

Setting the surface shape of the optical effective surface can be used to correct the optical effective surface of the optical element itself. In the case of an optical module of a projection exposure apparatus, setting a targeted deformation of the optical effective surface may be used to correct imaging errors caused by other components of the projection exposure apparatus. The deformation may thus be used to improve the imaging quality of the projection exposure apparatus in a manner analogous to the use of a manipulator.

In this case, the position relates primarily to the position of the optical element in the optical module, which itself usually has at least one active degree of freedom and can be positioned in up to six degrees of freedom.

For example, the at least one region which is deflectable parallel to the optical effective surface may be connected to an evaluation unit which is configured to detect mechanical stresses. This allows detection of a contact surfaces displacement which may be decoupled by an active deflection of the respective region.

In an embodiment, the Young's modulus of the material of the stiffening body may be greater than that of the material of the optical element by at least a factor of two, such as by a factor of three, for example by a factor of four. The higher the Young's modulus, in general, the thinner—and thus the lower in overall height—the stiffening body can be designed. This can help allow the production of an optical module whose height is similar to or even lower than that of a known module, whose main body predominantly comprises optical material. Moreover, by saving the comparatively expensive optical material, a more cost-effective optical module with the same installation space can be produced.

In addition, the stiffening body may be produced from a ceramic material, for example from silicon carbide. The ceramics usually have a comparatively high Young's modulus and comparatively low weight. In addition to the possibility of reducing the thickness of the optical module, the weight can also be reduced. In turn, this has positive effects on the control of the optical module, which can usually be positioned by way of actuators.

Furthermore, the stiffening body may have at least one thickened region. This allows the stiffness in this region to be further increased.

For example, at least one thickened region may take the form of a stiffening rib. As a result, stiffening of the stiffening body may also be achieved in the region in which the optical element is connected to the stiffening body by way of the connection elements. For example, the stiffening ribs may surround the optical element on at least one side, such as on at least two sides, for example on at least three sides. In this case, the stiffening ribs may project beyond the optical effective surface, i.e. have a greater height than the sum of the thicknesses of the optical element, the connection elements and the stiffening body below the optical element. The stiffening ribs may take a form that still allows processing of the optical effective surface after the assembly of the optical module.

In an embodiment, at least one thickened region may take the form of a reference region on which sensor elements are arranged. As a result, a relative movement of the sensors used for example for positioning the optical module can be achieved up to comparatively high natural frequencies of greater than 1500 Hz, for example above 2000 Hz. As explained further above, this can ensure stable position control of the optical module even if a low natural frequency in the optical element and/or in the connection between the optical element and the stiffening body leads to relative movements between the two components. In this case, the natural frequencies of the relative movements may lie in a range which has no effect or only a negligible effect on the imaging quality of the optical module.

In an embodiment, the optical element and/or the stiffening body may comprise fluid channels. A fluid for controlling the temperature of the optical element and/or of the stiffening body may flow through the fluid channels. As a result, the deviation of the temperature of the two components from their predetermined target temperature may be reduced, whereby the displacement of the contact surfaces of the connection elements on the optical element and on the stiffening body, which was already explained further above, can be minimized. The smaller the deflections desired for decoupling, the stiffer the decoupling regions may be for comparable forces and/or moments.

For example, the optical element may be a mirror.

Furthermore, at least one connection element may be arranged at the edge of the optical element between the optical element and the stiffening body in a manner at least predominantly in the direction parallel to the optical effective surface. An arrangement at the edge is desirable, especially in the case of an optical element in the form of a lens element. In the case of a mirror, an arrangement at the edge may bring about a reduction in the deformations in the region of the optical effective surface, which are caused by the introduction of forces and/or moments, as a result of the higher stiffness in the radial direction. The arrangement at the edge may also be implemented in addition to an arrangement of the connection elements in the direction of the optical axis, whereby it is for example possible to increase the stiffness in an xy-plane parallel to the optical effective surface.

In an embodiment, the at least one connection element may comprise at least one region which is deflectable parallel to the optical axis. As a result, manufacturing and/or assembly tolerances that arise in the direction of the optical axis during the assembly of the optical assembly may be compensated.

In an embodiment, the at least one connection element may take the form of a hybrid connection element. In this context, hybrid relates to an active embodiment of a region of the connection element, for example as an actuator in a direction parallel to the optical axis, and to a passive embodiment of a second region, for example as a spring parallel to the optical effective surface. This reduces the active degrees of freedom of the connection element, whereby a complexity of control and regulation, which becomes comparatively ever greater with an increasing number of active degrees of freedom, can be minimized for these active degrees of freedom.

For example, the region which is deflectable parallel to the optical axis may take the form of an actuator, and the region which is deflectable parallel to the optical effective surface may take the form of a passive decoupling element. Especially when arranging the connection element in the direction of the optical axis, the option of being able to actively set the distance between the back side of the optical element and the surface of the stiffening body is desirable. As already explained, this allows the optical effective surface to be set actively, and the optical element can be used as a manipulator for improving the imaging quality. A displacement of the optical element within the optical module in the xy-plane without a significant deformation of the optical effective surface, by contrast, can be corrected comparatively easily by the actuators that are usually formed on the optical module.

In an alternative, the region which is deflectable parallel to the optical axis may take the form of a passive decoupling element and the region which is deflectable parallel to the optical effective surface may take the form of an active decoupling element. This is desirable for example when the connection element is arranged radially, i.e. in the direction parallel to the optical effective surface. As a result, the active region can be deflected for decoupling purposes in the event of a thermal expansion of the optical element and/or stiffening body.

In an embodiment, the decoupling element may comprise a kinematic mechanism for decoupling. The kinematic mechanism may take the form of an active decoupling element and a passive decoupling element. In its simplest form, the kinematic mechanism may take the form of a leaf spring but may also have more complex embodiments formed with levers and joints. In this case, the joints may be embodied such that the forces and/or moments caused during a deflection of the connection element at least partially compensate one another. A conversion of the input movement into the output movement is also conceivable; this may find use especially in the case of actuators taking the form of active decoupling regions.

Furthermore, the kinematic mechanism may be arranged between a main body and a receptacle for receiving an actuator, especially in the case of a passive decoupling element. For example, the main body may be connected to the stiffening body by way of an adhesive connection. The adhesive connection may be arranged on both the lateral and end faces of the main body. The actuator connected to the receptacle may be connected to the optical element. The kinematic mechanism enables a deflection of the receptacle of the actuator vis-à-vis the main body, whereby a relative movement of the contact surfaces of the actuator can be decoupled according to the disclosure.

For example, the kinematic mechanism of the decoupling element may have an isotropic, i.e. directionally independent, stiffness in the deflection direction. For example, a similar or else exactly equal, for example low stiffness of the kinematic mechanism may be present for all directions in a plane, for example the xy-plane. The kinematic mechanism may have a comparatively high stiffness in a direction perpendicular thereto. This allows a high stiffness of the connection element in the direction of the active region and a comparatively low stiffness of the connection element in the direction of the passive region to be realized by way of the design of the kinematic mechanism. A high stiffness, which is desired for stable control of the optical module, can be realized thereby. As a result, it is possible for example to attain a lowest natural frequency of the optical module in an xy-plane parallel to the optical effective surface that is at least greater than 1500 Hz, for example greater than 2000 Hz, whereby stable control with a bandwidth of 150 Hz to 200 Hz is made possible. An active deflection of the active region can ensure sufficient decoupling in order to minimize a thermally induced displacement of the contact surfaces with respect to one another.

Furthermore, the stiffening body may have at least one thickened region. This allows the stiffness in this region to be further increased.

For example, at least one thickened region may take the form of a stiffening rib. As a result, stiffening of the stiffening body may also be achieved in the region in which the optical element is connected to the stiffening body by way of the connection elements. For example, the stiffening ribs may surround the optical element on at least one side, such as on at least two sides, for example on at least three sides. In this case, the stiffening ribs may project beyond the optical effective surface, i.e. have a greater height than the sum of the thicknesses of the optical element, the connection elements and the stiffening body below the optical element. The stiffening ribs may take a form that still allows processing of the optical effective surface after the assembly of the optical module.

In an embodiment, at least one thickened region may take the form of a reference region on which sensor elements are arranged. As a result, a relative movement of the sensors used for example for positioning the optical module can be achieved up to comparatively high natural frequencies of greater than 1500 Hz, for example above 2000 Hz. As explained further above, this can ensure stable position control of the optical module even if a low natural frequency in the optical element and/or in the connection between the optical element and the stiffening body leads to relative movements between the two components. In this case, the natural frequencies of the relative movements may lie in a range which has no effect or only a negligible effect on the imaging quality of the optical module.

In an embodiment, the optical element and/or the stiffening body may comprise fluid channels. A fluid for controlling the temperature of the optical element and/or of the stiffening body may flow through the fluid channels. As a result, the deviation of the temperature of the two components from their predetermined target temperature may be reduced, whereby the displacement of the contact surfaces of the connection elements on the optical element and on the stiffening body, which was already explained further above, can be minimized. The smaller the deflections desired for decoupling, the stiffer the decoupling regions may be for comparable forces and/or moments.

In an embodiment, the optical element may comprise a decoupling mechanism in the region of the connection of the connection element. The decoupling mechanism may be formed in an alternative or in addition to the decoupling regions formed in the connection elements.

For example, the decoupling mechanism may be provided by cavities formed in the optical element. The cavities may be integrated into the optical element already during the production thereof. This is possible comparatively easily, especially when producing the optical element by an additive method. In principle, the cavities may be produced using the same method that is used for the production of the fluid channels.

A projection exposure apparatus according to the disclosure for semiconductor lithography comprises an optical module according to any of the preceding embodiments. The use of the optical modules according to the disclosure furthermore allows the realization of projection exposure apparatuses even in the case of the optical elements becoming ever larger on account of the numerical aperture in more recent generations.

### BRIEF DESCRIPTION OF THE DRAWINGS

Exemplary embodiments and variants of the disclosure will be explained in more detail below on the basis of the drawing, in which:

FIG. 1 schematically shows a meridional section of a projection exposure apparatus for EUV projection lithography,

FIG. 2 schematically shows a meridional section of a projection exposure apparatus for DUV projection lithography,

FIG. 3 shows a schematic illustration of an optical module according to the disclosure,

FIG. 4 shows a schematic illustration of a detail of an embodiment of an optical module,

FIG. 5 shows an embodiment of an optical module,

FIG. 6 shows a further detail view of the disclosure,

FIGS. 7A-7B show an embodiment of a detail of the disclosure,

FIG. 8 shows an embodiment of a detail of the disclosure, and

FIGS. 9A-9C show further embodiments of an optical module according to the disclosure,

FIG. 10 shows an embodiment of an optical module according to the disclosure, and

FIG. 11 shows an embodiment of an optical module according to the disclosure.

### DETAILED DESCRIPTION

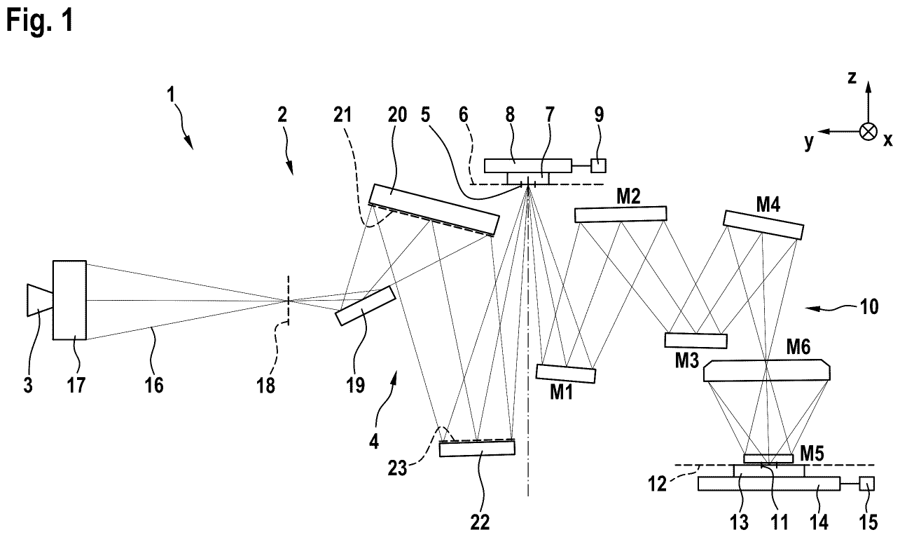

In the following text, the essential constituent parts of a microlithographic projection exposure apparatus 1 are described by way of example, initially with reference to FIG. 1. The description of the basic structure of the projection exposure apparatus 1 and the constituent parts thereof are to be understood as non-limiting.

One embodiment of an illumination system 2 of the projection exposure apparatus 1 has, in addition to a radiation source 3, an illumination optics unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable for example in a scanning direction by way of a reticle displacement drive 9.

A Cartesian xyz-coordinate system is depicted in FIG. 1 for explanation purposes. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15 for example in the y-direction. The displacement, firstly, of the reticle 7 by way of the reticle displacement drive 9 and, secondly, of the wafer 13 by way of the wafer displacement drive 15 may be implemented so as to be synchronized with one another.

The radiation source 3 is an EUV radiation source. The radiation source 3 emits for example EUV radiation 16, which is also referred to below as used radiation, illumination radiation or illumination light. The used radiation has for example a wavelength in the range of between 5 nm and 30 nm. The radiation source 3 may be a plasma source, for example a laser-produced plasma (LPP) source or a gas discharge-produced plasma (GDPP) source. It may also be a synchrotron-based radiation source. The radiation source 3 may be a free electron laser (FEL).

The illumination radiation 16 emanating from the radiation source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may constitute a separation between a radiation source module, comprising the radiation source 3 and the collector 17, and the illumination optics unit 4.

The illumination optics unit 4 comprises a deflection mirror 19 and, arranged downstream thereof in the beam path, a first facet mirror 20. The deflection mirror 19 may be a planar deflection mirror or alternatively a mirror with a beam-influencing effect that goes beyond the pure deflection effect. In addition to that or in an alternative, the deflection mirror 19 may be embodied as a spectral filter that separates a used light wavelength of the illumination radiation 16 from extraneous light of a wavelength differing therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which are also referred to below as field facets. FIG. 1 illustrates only some of these facets 21 by way of example.

The first facets 21 may take the form of macroscopic facets, for example rectangular facets or facets with an arcuate edge contour or an edge contour of part of a circle. The first facets 21 may take the form of planar facets or alternatively convexly or concavely curved facets.

As is known from DE 10 2008 009 600 A1, for example, the first facets 21 themselves may each also be composed of a multiplicity of individual mirrors, for example a multiplicity of micromirrors. The first facet mirror 20 may for example take the form of a microelectromechanical system (MEMS system). For details, reference is made to DE 10 2008 009 600 A1.

The illumination radiation 16 travels horizontally, i.e. in the y-direction, between the collector 17 and the deflection mirror 19.

In the beam path of the illumination optics unit 4, a second facet mirror 22 is arranged downstream of the first facet mirror 20. If the second facet mirror 22 is arranged in a pupil plane of the illumination optics unit 4, it is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can for example have a round, rectangular or else hexagonal boundary, or can alternatively be facets composed of micromirrors. In this regard, reference is likewise made to DE 10 2008 009 600 A1.

The second facets 23 may have planar or alternatively convexly or concavely curved reflection surfaces.

The illumination optics unit 4 thus forms a doubly faceted system. This basic principle is also referred to as a fly's eye integrator.

It may be desirable to arrange the second facet mirror 22 not exactly in a plane that is optically conjugate to a pupil plane of the projection optics unit 10. For example, the pupil facet mirror 22 may be arranged so as to be tilted relative to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In an embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may comprise exactly one mirror, or alternatively two or more mirrors arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In an embodiment of the illumination optics unit 4, the deflection mirror 19 may also be omitted, and so the illumination optics unit 4 may have exactly two mirrors downstream of the collector 17 in that case, specifically the first facet mirror 20 and the second facet mirror 22.

The imaging of the first facets 21 into the object plane 6 via the second facets 23, or using the second facets 23 and a transfer optics unit, is generally only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection optics unit 10 is a doubly obscured optical unit. The projection optics unit 10 has an image-side numerical aperture that is greater than 0.5 and may also be greater than 0.6 and may be, for example, 0.7 or 0.75.

Reflection surfaces of the mirrors Mi may take the form of free-form surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image shift in the y-direction between a y-coordinate of a center of the object field 5 and a y-coordinate of the center of the image field 11. This object-image shift in the y-direction may be of approximately the same magnitude as a z-distance between the object plane 6 and the image plane 12.

For example, the projection optics unit 10 may have an anamorphic design. For example, it has different imaging scales βx, βy in the x- and y-directions. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 thus leads to a reduction in size with a ratio of 4:1 in the x-direction, i.e. in a direction perpendicular to the scanning direction.

The projection optics unit 10 leads to a reduction in size of 8:1 in the y-direction, i.e. in the scanning direction.

Other imaging scales are likewise possible. Imaging scales with the same signs and the same absolute values in the x- and y-directions, for example with absolute values of 0.125 or 0.25, are also possible.

The number of intermediate image planes in the x-direction and in the y-direction in the beam path between the object field 5 and the image field 11 can be the same or can be different, depending on the embodiment of the projection optics unit 10. Examples of projection optics units with different numbers of such intermediate images in the x- and y-directions are known from US 2018/0074303 A1.

In each case one of the pupil facets 23 is assigned to exactly one of the field facets 21 for the purpose of forming a respective illumination channel for illuminating the object field 5. For example, this may result in illumination according to the Köhler principle. The far field is decomposed into a plurality of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is for example as homogeneous as possible. It can have a uniformity error of less than 2%. Field uniformity can be achieved by overlaying different illumination channels.

The illumination of the entrance pupil of the projection optics unit 10 may be defined geometrically by way of an arrangement of the pupil facets. The intensity distribution in the entrance pupil of the projection optics unit 10 may be set by selecting the illumination channels, for example the subset of the pupil facets that guide light. This intensity distribution is also referred to as illumination setting.

A likewise preferred pupil uniformity in the region of portions of an illumination pupil of the illumination optics unit 4 that are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays that is determined in pairs becomes minimal. This area is the entrance pupil or an area conjugate thereto in real space. For example, this area exhibits a finite curvature.

It may be the case that the projection optics unit 10 has different poses of the entrance pupil for the tangential beam path and for the sagittal beam path. In this case, an imaging element, for example an optical component of the transfer optics unit, should be provided between the second facet mirror 22 and the reticle 7. With the aid of this optical element, the different poses of the tangential entrance pupil and the sagittal entrance pupil can be taken into account.

In the arrangement of the components of the illumination optics unit 4 illustrated in FIG. 1, the pupil facet mirror 22 is arranged in an area conjugate to the entrance pupil of the projection optics unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

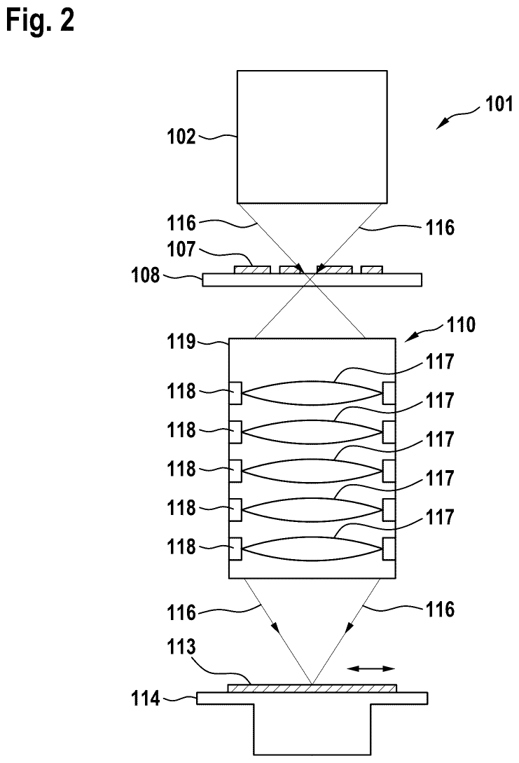

FIG. 2 schematically shows a meridional section through a further projection exposure apparatus 101 for DUV projection lithography, in which the disclosure can likewise be used.

The structure of the projection exposure apparatus 101 and the principle of the imaging are comparable with the structure and procedure described in FIG. 1. Identical components are denoted by a reference sign increased by 100 relative to FIG. 1, i.e. the reference signs in FIG. 2 start at 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, for example of 193 nm. The projection exposure apparatus 101 in this case essentially comprises an illumination system 102, a reticle holder 108 for receiving and exactly positioning a reticle 107, which is provided with a structure and is used to determine the later structures on a wafer 113, a wafer holder 114 for holding, moving, and exactly positioning this very wafer 113, and a projection lens 110, with a plurality of optical elements 117 held by way of mounts 118 in a lens housing 119 of the projection lens 110.

The illumination system 102 provides DUV radiation 116 for the imaging of the reticle 107 on the wafer 113. A laser, a plasma source or the like may be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optics unit 101 with the lens housing 119 does not differ in principle from the structure described in FIG. 1 and is therefore not described in further detail.

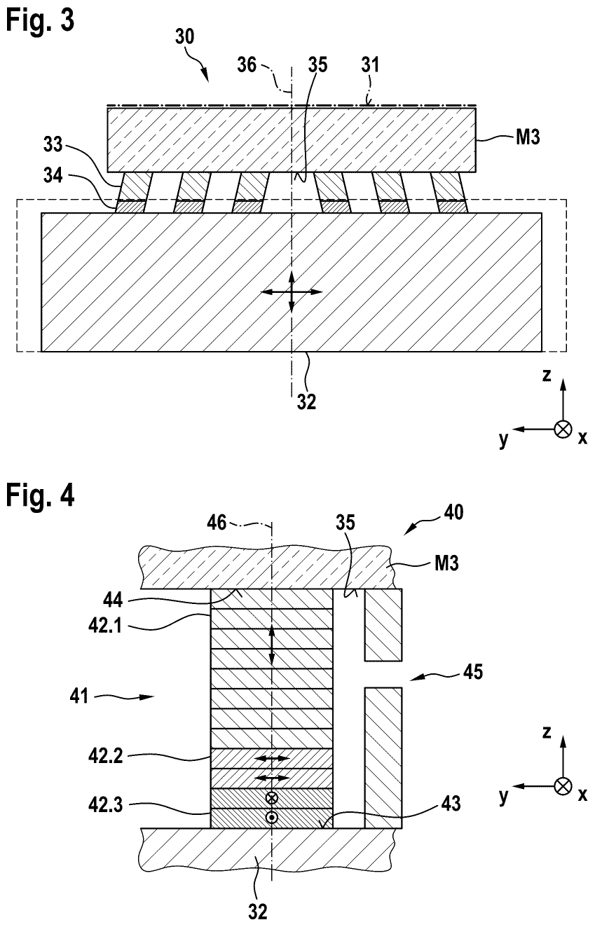

FIG. 3 shows a schematic illustration of an optical module in the form of a mirror module 30, which in the example shown comprises the mirror M3 from the EUV projection exposure apparatus 1 explained in FIG. 1. The mirror M3 comprises an optical effective surface 31 indicated by a dash-dotted line, on which the used radiation (not illustrated) is incident during operation of the projection exposure apparatus 1. Furthermore, the mirror module 30 comprises a stiffening body 32, which is arranged on the back side 35 of the mirror M3 opposite the optical effective surface 31 and is connected to the mirror M3 by way of connection elements 33. The connection elements 33 are embodied in the direction of an optical axis 36 of the mirror M3, with the optical axis 36 corresponding to the axis of symmetry of the mirror M3 in the example shown. In the case of curved mirrors, as used in EUV projection exposure apparatuses 1 for example, the optical axis is understood to be the axis perpendicular to the mirror surface passing through the vertex of the mirror. The connection elements 33 may take an active form, for example as actuators (see FIG. 4), a passive form, for example as a flexure, or a combination of the two.

In combination with the connection elements 33, the stiffening body 32 brings about a stiffening of the mirror M3, especially in the z-direction, and as a result the thickness of the mirror may be chosen to be smaller in comparison with previous mirrors of the same radius.

In the embodiment illustrated in FIG. 3, the stiffening body 32 comprises a material which differs from the mirror material. For example, ceramics such as silicon carbide are possible in this context. Ceramics of this type have a comparatively high Young's modulus. It is desirable if the material of the stiffening body 32 has a Young's modulus that is greater than that of the mirror material by at least a factor of two, such as by at least a factor of three, for example at least a factor of four. As a result, realization of the mirror module 30 involves far less material while the overall stiffness remains practically unchanged, and this has, inter alia, a positive effect on the installation space and also on the overall mass as well as on the production costs of the mirror module 30 owing to the fewer materials needed.

The desired high control bandwidth for positioning the mirror module 30 is made possible by the use of the stiffening body 32, even in the case of a thinner mirror M3 overall. For example, position control of the mirror module 30 can be rendered possible on account of a high natural frequency of the mirror of more than 1500 Hz, for example of more than 2000 Hz. Furthermore, a deformation of the optical effective surface 31, which is decisive for the imaging quality and which is caused by mechanical excitation for example, may be kept low during operation.

The stiffness of the mirror module 30 in the lateral xy-plane, i.e. perpendicular to the z-direction, is less critical as a matter of principle, and so there even is a sufficiently large lateral stiffness of the mirror module 30, including the connection elements 33 and the stiffening body 32, for the solution shown in the figure by way of example.

The different coefficients of thermal expansion of the mirror material, e.g. ULE®, and the ceramic of the stiffening body 32 lead to different expansions of the mirror M3 and of the stiffening body 32 during heating of the mirror M3 and of the stiffening body 32 that occurs during operation. For example, the heating may be caused by an absorption of the used radiation and/or the effect of other heat sources on the components M3, 32.

This situation is illustrated somewhat exaggerated in FIG. 3 by virtue of the expansion of the stiffening body 32 arising in the case of the arrangement heating up being depicted using dashed lines, whereas the expansion of the mirror M3 remains virtually unchanged on account of the very low coefficient of thermal expansion of the mirror material.

In this case, decoupling regions 34 present in the connection elements 33 can compensate the resultant relative movement between the back side 35 of the mirror M3 and the stiffening body 32, especially in the xy-plane. For example, the decoupling region 34 can be created by way of an appropriate choice of material or a corresponding shape.

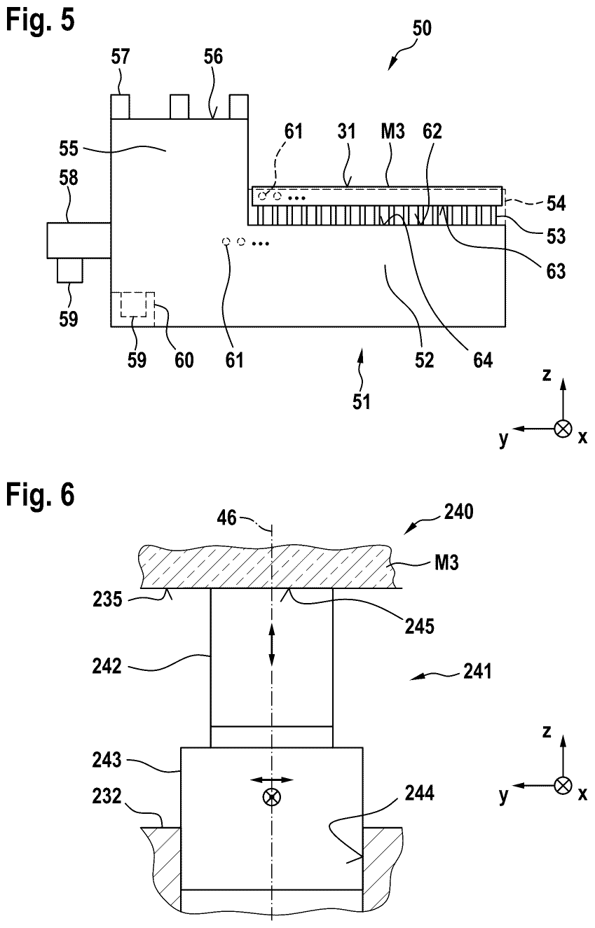

By contrast, a uniform expansion of the mirror M3 and/or of the stiffening body 32 in the z-direction that is uniform over the xy-plane is not critical since virtually all mirror modules 30 are mounted in a positionable manner on actuators (see FIG. 5), and so a displacement in the z-direction of the optical effective surface 31 relevant to the imaging can be compensated by a positioning of the mirror module 30.

FIG. 4 shows a schematic illustration of a detail of an embodiment of an optical module in the form of a mirror module 40, which comprises a connection element in the form of an actuator 41 aligned in the direction of the optical axis 46. The actuator 41 in the form of a piezoelectric actuator comprises three actuator regions 42.1, 42.2, 42.3 that are controllable separately from one another by a controller (not depicted here) connected to the mirror module 40. The upper region 42.1, which acts in the z-direction, may be used to compensate for manufacturing tolerances of the contact surface 43 on the stiffening body 32 and of the contact surface 44 on the mirror M3 and for manufacturing tolerances with regard to the length of the actuators 41. Depending on the component M3, 32, 41, the manufacturing tolerances may be in the range of 2 to 20 micrometers, for example for the ceramic of the stiffening body 32, or in the order of a few nanometers on the back side 35 of the optical material of the mirror M3. Possible connection techniques such as adhesion, laser bonding, surface activated bonding, anodic bonding, glass frit bonding, adhesive bonding, eutectic bonding, reactive bonding, silicate bonding or the like, might not be able to sufficiently compensate for the manufacturing tolerances. The remaining deviations are typically in the range from one to three micrometers.

Furthermore, the travel in the z-direction can be used to compensate thermally induced deformations of the optical effective surface 31 (FIG. 3). In addition, the travel may be used for targeted deformation of the optical effective surface 31, for example for correcting other imaging errors which are not caused in the mirror module 40 itself.

The two lower regions 42.2, 42.3 of the actuator 41, which can be deflected perpendicularly to each other in the x-direction and the y-direction, with this being depicted in FIG. 4 by arrows in the regions 42.2, 42.3, form the decoupling region, as explained in FIG. 3, of the connection element in the form of the actuator 41 and act as a lateral decoupling element between the mirror M3 and the stiffening body 32. By displacing the lower regions 42.2, 42.3, the actuator 41 compensates for the displacements in the xy-plane that occur between the contact surfaces 43, 44 on account of the different thermal expansions. The displacement of the respective contact surfaces 43, 44 may be determined by way of a model-based method, for example, which is based on a temperature measured at one or more points of the mirror module 40 by sensors (not illustrated). The displacement is determined for each of the actuators 41 arranged in the mirror module 40.

An alternative approach for determining the displacement lies in the alternating use of the lower regions 42.2, 42.3 of the actuator 41 as a sensor and as an actuator. When used as a sensor, the piezoelectric effect is exploited, i.e. the generation of a voltage by generating a mechanical stress in the material. When used as an actuator, a voltage is applied such that the material expands or contracts, i.e. the so-called inverse piezoelectric effect is used.

The effect of thermal change processes on the material is slow in comparison with the effect due to a mechanical excitation, and so the alternating operation has a sufficient speed for compensating the resulting displacements.

As a further solution, the displacement may also be determined by a position sensor 45 which is arranged in the immediate vicinity of the actuator 41, the position sensor measuring the displacement between the mirror M3 and the actuator 41.

FIG. 5 shows an embodiment of an optical module in the form of a mirror module 50, which comprises a stiffening body 51 that has been optimized for different desired properties. In addition to the higher Young's modulus already explained further above, the stiffness may be optimized further by the geometry of the stiffening body 51. The stiffening body 51 has a receiving region 52 for receiving the mirror M3. The receiving region 52 has a receiving surface 64 which corresponds to the back side of the mirror M3 and on which the connection elements in the form of actuators 53 are arranged. For further stiffening, the receiving region 52 comprises stiffening ribs 54, which are formed as thickened regions on the sides lying parallel to the plane of the drawing and which are depicted in FIG. 5 using dashed lines and in a transparent manner. In this case, the stiffening ribs 54 take such a form that the optical effective surface 31 of the mirror M3 can still be processed after the mirror module 50 has been assembled. The receiving region 52 ensures a sufficiently high stiffness, especially in the z-direction, while having a minimal thickness, whereby it is possible to obtain an overall thickness of the mirror module 50 that is less than or equal to the thickness of conventionally produced mirrors made of optical material. In the embodiment depicted in FIG. 5, a further thickened region in the form of a reference region 55 is present on the left-hand side of the stiffening body 51, the reference region projecting beyond the optical effective surface 31 in the z-direction and being stiffer than the receiving region 52, especially in the z-direction, on account of its greater thickness. Sensors or sensor targets 57 as sensor elements used for the positioning of the mirror module 50 are arranged on the reference surface 56 of the reference region 55, which faces upward like the optical effective surface 31. As a result of the very high stiffness of the reference region 55 in all degrees of freedom, the relative movement on account of eigenmodes of the mirror module 50 between the three to six sensors 57 is reduced to a value which ensures a high control bandwidth for positioning the mirror module 50.

Lugs 58 for connecting the actuators 59 used for positioning purposes are formed adjacent to the reference region 55. In an alternative, the actuators 59 may also be connected in pockets 60 which are formed within the reference region 55 and which are depicted using dashed lines in FIG. 5.

The transitions between the various regions 52, 54, 55, 58 may have radii or other profiles in order to optimize the stress profiles and the manufacturability of the stiffening body 51. The mirror M3 and the receiving region 52 of the stiffening body 51 have fluid channels in the form of cooling channels 61, whereby the temperature difference between the mirror M3 and the stiffening body 51 can be reduced to a minimum. This is desirable in that the displacement of the contact surfaces 62, 63 of the actuators 53 between the mirror M3 and the stiffening body 51 occurring on account of the different coefficients of thermal expansion is minimized. The smaller the displacement between the mirror M3 and the stiffening body 51, the less travel of the lower regions 42.2, 42.3 (FIG. 4) of the actuator 41 (FIG. 4), which corresponds to the construction of the actuator 53, is desired. The travel is virtually proportional to the installation height of the lower actuator regions 42.2, 42.3, whereby the thickness of the mirror module 50 is further reduced as a result of a minimization of the travel.

The optical module 30, 40, 50 according to the disclosure can be adapted very variably depending on the respective desired properties by way of selecting the materials used, the connection elements 33, 41, 53 and the geometry of the stiffening body 32, 51, wherein the embodiments described only show individual embodiments and the disclosure cannot be restricted thereto in any way.

FIG. 6 shows a schematic illustration of a detail of an embodiment of an optical module in the form of a mirror module 240 with a mirror M3, with the mirror module 240 comprising a hybrid connection element 241 having an actuator 242 and a decoupling region in the form of a decoupling element 243. In this context, hybrid refers to an active embodiment of the actuator 242 and a passive embodiment of the decoupling element 243. The actuator 242 in the form of a piezoelectric actuator is connected to a controller (not illustrated) connected to the mirror module 240 and can be controlled thereby. The actuator 242 acting in the z-direction may be used to compensate for manufacturing tolerances of the elements M3, 232, 241 involved in the connection. Depending on the component M3, 232, 241, these manufacturing tolerances may be in the range of 2 to 20 micrometers, for example for the ceramic of the stiffening body 232, or in the order of a few nanometers on the back side 235 of the optical material of the mirror M3. Possible connection techniques such as adhesion, screen printing, laser bonding, surface activated bonding, anodic bonding, glass frit bonding, adhesive bonding, eutectic bonding, reactive bonding, silicate bonding or the like, might not be able to sufficiently compensate for the manufacturing tolerances. The remaining deviations are typically in the range from one to three micrometers.

Furthermore, the travel in the z-direction can be used to compensate thermally induced deformations of the optical effective surface 31 (FIG. 3). In addition, the travel may be used for targeted deformation of the optical effective surface 31, for example for correcting imaging errors which are not caused in the mirror module 240 itself.

The decoupling element 243 is designed such that it has a decoupling effect in the x-direction and in the y-direction, this being indicated in FIG. 6 by double-headed arrows in the decoupling element 243. Hence it acts as a lateral decoupling mechanism between the mirror M3 and the stiffening body 232. By way of its deformation, the decoupling element 243 compensates for the displacements in the xy-plane that occur between the contact surfaces 244, 245 on account of the different thermal expansions. In this case, the stiffness of the decoupling element 243, as explained further above, is sufficient for the lowest natural frequency of the mirror module 240 in the xy-plane to be at least greater than 1500 Hz, for example greater than 2000 Hz. At the same time, the stiffness is low enough so that the parasitic forces and moments generated by the deflection of the decoupling element 243 do not cause any significant deformations of the optical effective surface 31 (FIG. 3). The displacement of the respective contact surfaces 244, 245 is compensated for passively by the decoupling elements 243, in comparison with an active solution. Thus, the example shown does not require a determination of the displacement by a model-based method on the basis of measured temperature or position values.

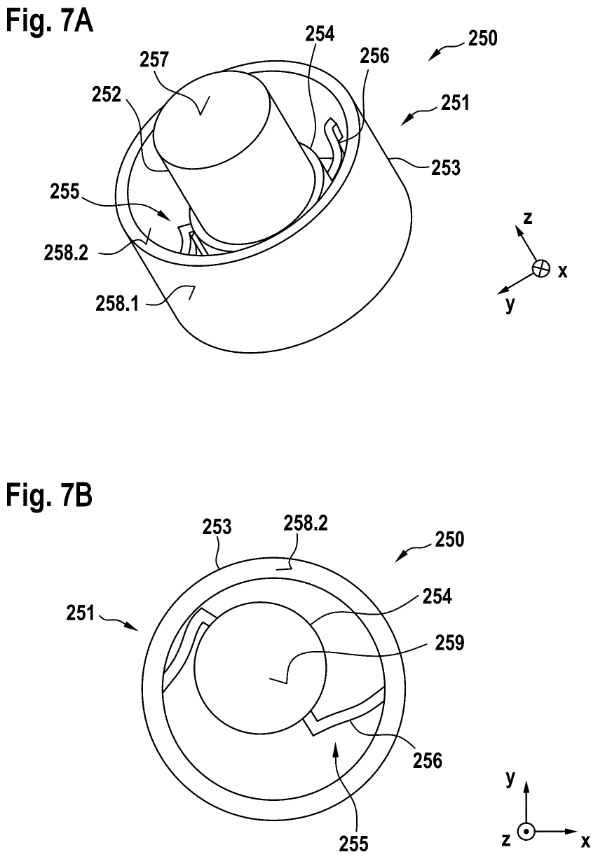

FIG. 7A shows a detail of the mirror module 240, in which a first embodiment of a connection element 250 as used in FIG. 6 (reference sign 241 therein) is depicted. The connection element 250 comprises a decoupling element 251 and an actuator 252.

The decoupling element 251 comprises a hollow-cylindrical main body 253 and a cylindrical receptacle 254 which are connected to each other in the example shown by way of a kinematic mechanism 255 comprising two levers 256. The kinematic mechanism 255 allows relative movement of the receptacle 254 with respect to the main body 253. The stiffness of the levers 256 is designed such that the mirror module 240 (FIG. 6) has a sufficiently high natural frequency for stable position control both in the z-direction and in the lateral xy-direction. In this case, the stiffness of the connection element 250 in the z-direction is determined not only by the stiffness of the actuator 252 but predominantly by the height (z-direction) of the levers 256. By contrast, the stiffness in the lateral direction (xy-plane) is influenced by the thickness of the levers 256, which take the form of leaf springs in the example shown, and the length thereof. In the example shown in FIG. 7A, the connection element 250 is monolithic; however, it may also be of multi-part form in an alternative.

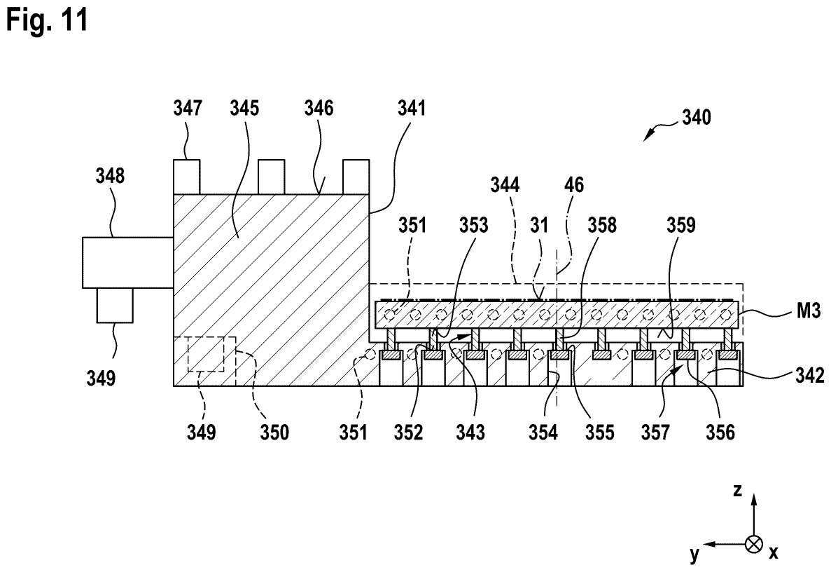

On its outer lateral surface, the main body 253 comprises a contact surface 258.1 to the stiffening body 232 (FIG. 6), by way of which the connection element 250 may be connected to the stiffening body 232 (FIG. 6) by way of an adhesive connection. In an alternative, the connection element 250 may also be connected to the stiffening body 341 by way of a contact surface 258.2 that is formed in the positive z-direction in FIG. 6a (FIG. 11).

On its top side facing the positive z-direction, the actuator 252 comprises a contact surface 257 for connecting it to the mirror M3 (FIG. 7).

FIG. 7B shows a plan view of the connection element 250 (FIG. 7A) in a deflected state. The actuator 252 (FIG. 7A) has not been illustrated, and so the contact surface 259 of the receptacle 254 between the actuator 252 and the decoupling element 251 can be seen. The deformation of the levers 256 is clearly evident, whereby, by way of the connection element 250, at least a local displacement of the mirror M3 (FIG. 6), which is connected by way of the actuator (not illustrated), is made possible in the region of the contact surface 245 of the actuator 242 (FIG. 6) on the mirror M3 and the stiffening body 232 (FIG. 6) connected to the main body 253.

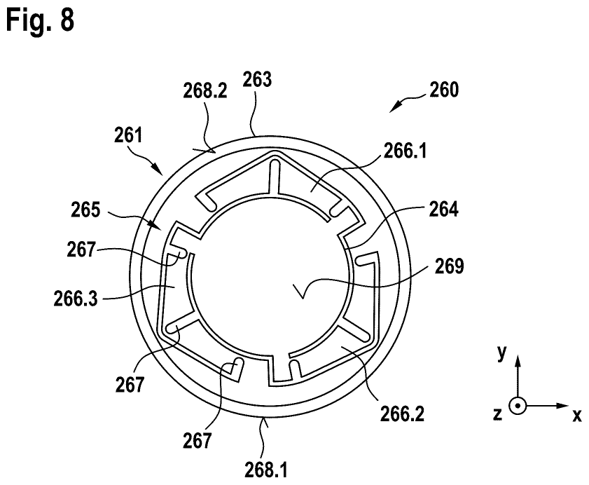

FIG. 8 shows a plan view of an embodiment of a connection element 260, with no actuator being depicted like in FIG. 7B. The construction of the connection element 260 is similar to the connection element 250 explained in FIG. 7A, with corresponding elements being denoted, where appropriate, by reference signs that have been increased by 10 in relation to the designation in FIG. 7B. In contrast to the kinematic mechanism 255 explained in FIG. 7A, the kinematic mechanism 265 comprises three levers 266.1, 266.2, 266.3, which are aligned concentrically with respect to the lateral surface of the receptacle 264 and each connected radially to the inner lateral surface of the main body 263. In comparison with the lever 256 (FIG. 7B), the levers 266.1, 266.2, 266.3 have a large thickness, with the levers 266.1, 266.2, 266.3 each having cutouts 267 at three points in the example shown such that the thickness is locally reduced to a minimum.

This is desirable in that the stiffness of the levers 266.1, 266.2, 266.3 can be set radially in a targeted manner in accordance with the desired properties regarding the lateral (xy-plane) stiffness of the connection element 260, in a manner virtually independently of the stiffness in the z-direction. For example, the lateral stiffnesses may be designed such that the stiffness in the xy-plane is isotropic, i.e. directionally independent. Moreover, the cutouts 267 are formed alternately from the receptacle 264 to the main body 263 and from the main body 263 to the receptacle 264. This is desirable in that the deflection of the receptacle 264 vis-à-vis the main body 263 causes lower forces and/or moments since these at least partially cancel out on account of the alternating arrangement of the local minima in the thickness of the levers 266.1, 266.2, 266.3.

In the example shown, the connection element 260 is also produced monolithically.

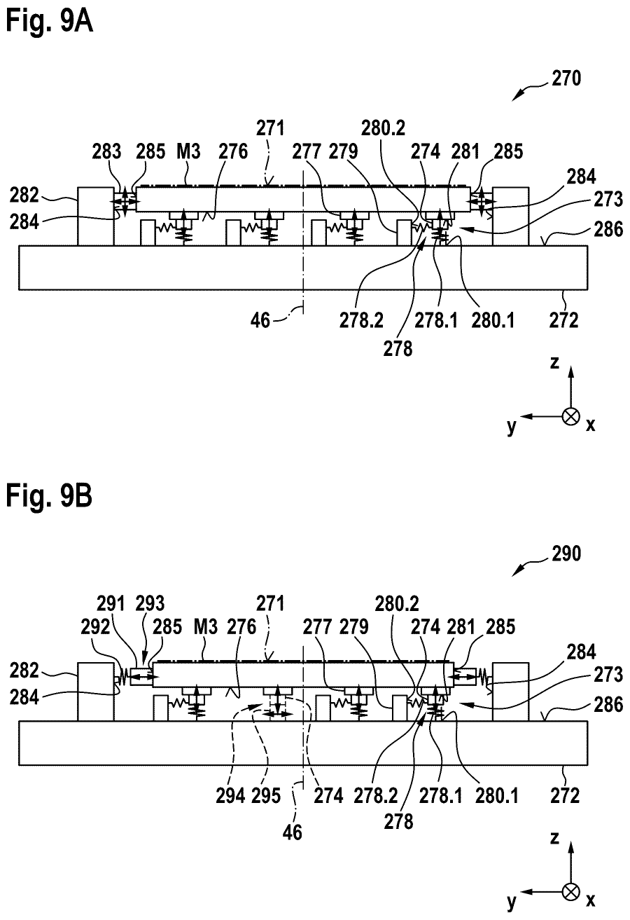

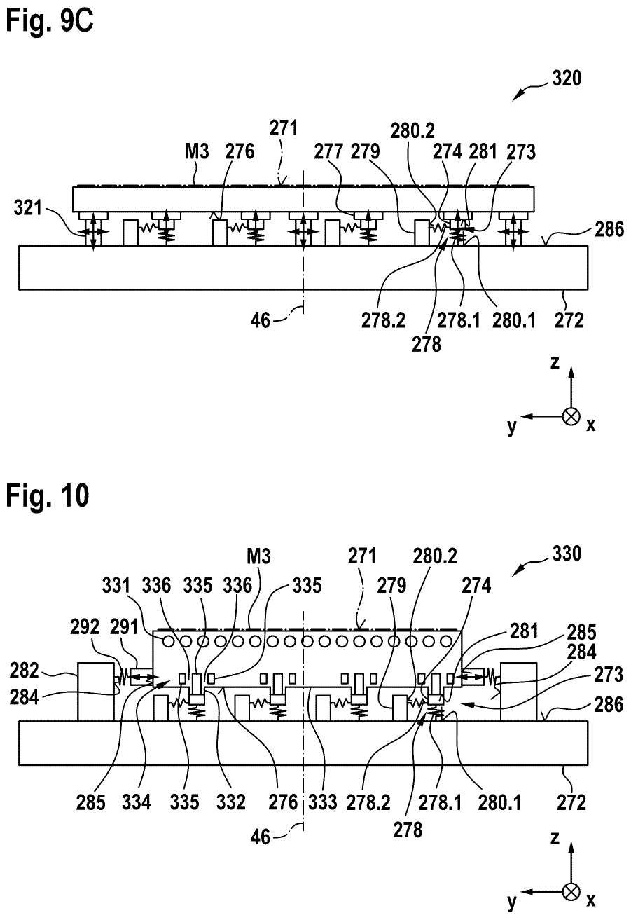

FIG. 9A shows a schematic illustration of an embodiment of a mirror module 270 with an optical element in the form of a mirror M3, which is connected to a stiffening body 272 by way of connection elements 273. On the back side 276 opposite the optical effective surface 271, the mirror M3 has bulges 277 which comprise a contact surface 281 for connecting the connection elements 273. The connection elements 273 are connected to the mirror M3 by actuators 274 on the contact surfaces 281. The example of FIG. 9A depicts decoupling elements 278 in the form of two springs 278.1, 278.2. The first spring 278.1 represents the stiffer connection of the connection element 273 in the z-direction and is connected to a surface 286 of the stiffening body 272 opposite the back side 276 of the mirror M3 by way of a first contact surface 280.1. The second spring 278.2 represents the connection in the xy-direction with the decoupling action, with the shown example only depicting a spring 278.2 in the y-direction. The second spring 278.2 is connected by way of a second contact surface 280.2 to an arm 279 formed on the stiffening body 272 in the z-direction.

Furthermore, the mirror module 270 comprises additional actuators 283 which are arranged radially between a flange 282 of the stiffening body 272 and the mirror M3. The actuators 283 are connected to the stiffening body 272 by way of contact surfaces 284 of the flange 282 and to the mirror M3 by way of the lateral surface 285 of the latter, which is at least partially in the form of a contact surface.

The additional actuators 283 increase the stiffness in the lateral (xy-plane) direction and have at least one degree of freedom in the radial direction and one degree of freedom in the z-direction. Together with the actuators 274 of the connection elements 273, the degree of freedom is controlled by a controller (not depicted here) for compensating deformations of the optical effective surface 271. The radial degrees of freedom may serve to compensate for the thermal deformations that occur as a result of the different coefficients of thermal expansion of the materials of the mirror M3 and of the stiffening body 272 and the resultant change in the distance between the contact surfaces 284, 285 by tracking, i.e. controlling the actuators 283. The radial degree of freedom of the actuators 283 thus acts as an active decoupling region of the connection element in the form of an actuator 283. Depending on the desired properties, the actuators 283 may also be used for an additional deformation of the mirror M3 and of the optical effective surface 271 arranged thereon.

FIG. 9B shows a schematic illustration of an embodiment of a mirror module 290. It differs from the mirror module 270 explained in FIG. 9A merely in terms of the radially arranged connection element 293, which comprises a decoupling element 292 for connecting an actuator 291 to the flange 282. The actuator 291 comprises at least one degree of freedom in the radial direction and no degree of freedom in the z-direction and for example takes the form of an electrostrictive actuator. To compensate for the movement in the z-direction between the mirror M3 and the stiffening body 272, a decoupling element 292, illustrated as a spring in the example shown in the figure, is arranged between the actuator 291 and the contact surface 284. Thus, the decoupling element 292 is designed to be soft in the z-direction and stiff in the radial direction. The radial degree of freedom of the actuators 283 thus acts as an active decoupling region of the connection element 293.

Furthermore, FIG. 9B illustrates an alternative connection element 294 which, in comparison with the hybrid connection elements 273 with a decoupling region in the form of a passive decoupling element 278, has an active decoupling region in the form of an actuator 295. In a manner comparable with the actuator 291 of the radially arranged connection element 293, the actuator 295 is deflected between the mirror M3 and the stiffening body 272 in the event of different expansions of the two components M3, 272, in such a way that no forces, moments and/or stresses are caused or transmitted, i.e. these are decoupled. The connection element 294 may also find use in the embodiment depicted in FIG. 9A, as an alternative to the hybrid connection elements 273.

FIG. 9C shows a schematic illustration of an embodiment of a mirror module 120. In contrast to the mirror modules 270, 290 depicted in FIGS. 9A, 9B, additional connection elements in the form of actuators 321 for stiffening the mirror module 320 are arranged between the back side 276 of the mirror M3 and the stiffening body 272. The actuators 321 each have a degree of freedom in the z-direction, x-direction and y-direction. These increase the stiffness between mirror M3 and stiffening body 272 in the xy-direction. The number of actuators 321 or the ratio between the actuators 321 and hybrid connection elements 273 depends firstly on the desired stiffness of the mirror module M3 in the xy-direction and secondly on the control which becomes comparatively more complex with increasing active degrees of freedom. In the case of thermally induced different displacements of the contact surfaces of the actuators 321 on the stiffening body 272 and on the back side 276 of the mirror M3, the actuators 321 are actively deflected accordingly in the xy-direction for decoupling purposes.

FIG. 10 shows a schematic illustration of an embodiment of a mirror module 330 according to the disclosure. The mirror module 330 is constructed identically to the mirror module 290 in FIG. 9B. In comparison with the examples explained further above, in the region below the optical effective surface 271 the mirror M3 comprises a number of cooling channels 331, through which a fluid, for example high-purity water, flows in order to control the temperature of the mirror M3. The connection in the form of a bulge 332 for the connection element 273 is decoupled vis-à-vis a main body 333 of the mirror M3 when compared to the bulge 277 (FIG. 9B), with the bulge 332 and the main body 333 being monolithic. The decoupling mechanism 334 is brought about by the creation of cavities 335 and connecting elements 336, which act as springs, in the material of the mirror M3. The decoupling mechanism 334 brings about a minimization of the parasitic forces and moments introduced at the contact surface 281 of the bulge 332 due to the connection of the actuator 283. For example, this might be caused by an adhesive connection used for the connection or by assembly and manufacturing tolerances.

FIG. 11 shows an embodiment of an optical module in the form of a mirror module 340, which comprises a stiffening body 341 that has been optimized for different desired properties. In addition to the higher Young's modulus already explained further above, the stiffness may be optimized further by the geometry of the stiffening body 341. The stiffening body 341 has a receiving region 342 for receiving the mirror M3. The receiving region 342 has through-bores 354, in which shoulders 355 are formed as contact surfaces for connecting the connection elements 343. As explained in FIG. 7A, the main bodies 356 of the decoupling elements 357 of the connection element 343 are connected at the end face to the shoulder 355, for example by way of an adhesive connection (not depicted here). For example, further possible connection techniques include adhesion, screen printing, laser bonding, surface activated bonding, anodic bonding, glass frit bonding, adhesive bonding, eutectic bonding, reactive bonding, silicate bonding or the like.

The actuators 358 of the connection elements 343 are connected to the back side 359 of the mirror M3 through the through-bore 354 which is tapered in the direction of the mirror M3 above the shoulder 355. For further stiffening, the receiving region 342 comprises stiffening ribs 344, which are depicted in FIG. 11 by dashed lines and in a transparent manner. In this case, the stiffening ribs 344 take such a form that the optical effective surface 31 of the mirror M3 can still be processed after the mirror module 340 has been assembled. The receiving region 342 ensures a sufficiently high stiffness, especially in the z-direction, while having a minimal thickness, whereby it is possible to obtain an overall thickness of the mirror module 340 that is less than or equal to the thickness of conventionally produced mirrors made of optical material.

In the embodiment depicted in FIG. 11, a reference region 345 is formed on the left-hand side of the stiffening body 341, the reference region projecting beyond the optical effective surface 31 in the z-direction and being stiffer than the receiving region 342, especially in the z-direction, on account of its greater thickness. Sensors 347 used for the positioning of the mirror module 340 are arranged on the reference surface 346 of the reference region 345, which faces upward like the optical effective surface 31. As a result of the very high stiffness of the reference region 345 in all degrees of freedom, the relative movement on account of eigenmodes of the mirror module 340 between the three to six sensors 347 is reduced to a value which ensures a high control bandwidth for positioning the mirror module 340.

Lugs 348 for connecting the actuators 349 used for positioning purposes are formed adjacent to the reference region 345. In an alternative, the actuators 349 may also be connected in pockets 350 which are formed within the reference region 345 and which are depicted using dashed lines in FIG. 11.

The transitions between the various regions 342, 344, 345, 348 may have radii or other profiles in order to optimize the stress profiles and the manufacturability of the stiffening body 341. The mirror M3 and the receiving region 342 of the stiffening body 341 have cooling channels 351, whereby the temperature difference between the mirror M3 and the stiffening body 341 can be reduced. This is desirable in that the displacement of the contact surfaces 352, 353 of the connection elements 343 between the mirror M3 and the stiffening body 341 occurring on account of the different coefficients of thermal expansion is reduced. The smaller the displacement between the mirror M3 and the stiffening body 341, the less travel has to be compensated for by the decoupling element 357, whereby a stiffer construction of the levers 266 arranged in the decoupling elements 357 is possible for the same mechanical load (FIG. 8).

List of reference signs

| | |
|---|---|
| 1 | Projection exposure apparatus |
| 2 | Illumination system |
| 3 | Radiation source |
| 4 | Illumination optics unit |
| 5 | Object field |
| 6 | Object plane |
| 7 | Reticle |
| 8 | Reticle holder |
| 9 | Reticle displacement drive |
| 10 | Projection optics unit |
| 11 | Image field |
| 12 | Image plane |
| 13 | Wafer |
| 14 | Wafer holder |
| 15 | Wafer displacement drive |
| 16 | EUV radiation |
| 17 | Collector |
| 18 | Intermediate focal plane |
| 19 | Deflection mirror |
| 20 | Facet mirror |
| 21 | Facets |
| 22 | Facet mirror |
| 23 | Facets |
| 30 | Optical module |
| 31 | Optical effective surface |
| 32 | Stiffening body |
| 33 | Connection element |
| 34 | Decoupling region |
| 35 | Mirror back side |
| 36 | Optical axis |
| 40 | Optical module |
| 41 | Connection element |
| 42.1-42.3 | Actuator regions |
| 43 | Stiffening element contact surface |
| 44 | Optical element contact surface |
| 45 | Position sensor |
| 46 | Optical axis |
| 50 | Optical module |
| 51 | Stiffening body |
| 52 | Receiving region |
| 53 | Connection element |
| 54 | Stiffening ribs |
| 55 | Reference region |
| 56 | Reference region surface |
| 57 | Sensor positioning mirror module |
| 58 | Lug |
| 59 | Actuators for positioning mirror module |
| 60 | Pocket |
| 61 | Cooling channels |
| 62 | Stiffening element contact surface |
| 63 | Optical element contact surface |
| 64 | Receiving surface |
| X | x-direction |
| y | y-direction |
| z | z-direction |
| 101 | Projection exposure apparatus |
| 102 | Illumination system |
| 107 | Reticle |
| 108 | Reticle holder |
| 110 | Projection optics unit |
| 113 | Wafer |
| 114 | Wafer holder |
| 116 | DUV radiation |
| 117 | Optical element |
| 118 | Mounts |
| 119 | Lens housing |
| M1-M6 | Mirror |
| 242 | Actuator |
| 243 | Decoupling element |
| 244 | Stiffening element contact surface |
| 245 | Optical element contact surface |
| 250 | Connection element |
| 251 | Decoupling element |
| 252 | Actuator |
| 253 | Main body |
| 254 | Actuator receptacle |
| 255 | Kinematic mechanism |
| 256 | Lever |
| 257 | Contact surface to mirror |
| 258.1, | Contact surface to stiffening body |
| 259 | Actuator contact surface to decoupling element |
| 260 | Connection element |
| 263 | Main body |
| 264 | Actuator receptacle |
| 265 | Kinematic mechanism |
| 266 | Lever |
| 267 | Cutout |
| 270 | Mirror module |
| 271 | Optical effective surface |
| 272 | Stiffening body |
| 273 | Connection element |
| 274 | Actuator |
| 276 | Mirror back side |
| 277 | Bulge |
| 278 | Decoupling element |
| 278.1, | Springs |
| 279 | Arm |
| 280.1, | Stiffening body contact surface |
| 281 | Optical element contact surface |
| 282 | Flange |
| 283 | Actuator (radially arranged) |
| 284 | Connection contact surface |
| 285 | Mirror lateral surface contact surface |
| 286 | Stiffening body surface |
| 290 | Mirror module |
| 291 | Actuator |
| 292 | Spring |
| 293 | Connection element |
| 294 | Connection element |
| 295 | Actuator |
| 320 | Mirror module |
| 321 | Actuator |
| 330 | Mirror module |
| 331 | Cooling channel |
| 332 | Bulge |
| 333 | Main body |
| 334 | Decoupling mechanism |
| 335 | Cavity |
| 336 | Connecting element |
| 340 | Mirror module |
| 341 | Stiffening body |
| 342 | Receiving region |
| 343 | Connection element |
| 344 | Stiffening ribs |
| 345 | Reference region |
| 146 | Reference region surface |
| 147 | Sensor positioning mirror module |
| 148 | Lug |
| 149 | Actuators for positioning mirror module |
| 150 | Pocket |
| 151 | Cooling channels |
| 152 | Stiffening element contact surface |
| 153 | Optical element contact surface |
| 154 | Through-bore |
| 155 | Shoulder |
| 156 | Main body |
| 157 | Decoupling element |
| 158 | Actuator |
| 159 | Mirror back side |

What is claimed is:

1. An optical module, comprising:
an optical element comprising an optical effective surface;
in a stiffening body; and
an actuator connecting the optical element and the stiffening body,
wherein:
the actuator comprises a region mechanically decoupling the stiffening body and the optical element parallel to the optical effective surface;
the region of the actuator is deflectable parallel to the optical effective surface; and
a Young's modulus of a material of the stiffening body is at least twice a Young's modulus of a material of the optical element.

2. The optical module of claim 1, wherein the stiffening body comprises a ceramic.

3. The optical module of claim 1, wherein the actuator is between the optical element and the stiffening body in a direction of an optical axis of the optical module.

4. The optical module of claim 1, wherein the actuator comprises at least two regions which are deflectable perpendicular to each other and parallel to the optical effective surface.

5. The optical module of claim 1, wherein the region is actively controllable.

6. The optical module of claim 1, wherein the actuator comprises a region which is deflectable perpendicular to the optical effective surface.

7. The optical module of claim 1, further comprising an evaluation unit connected to the region of the actuator, wherein the evaluation unit is configured to detect mechanical stresses.

8. The optical module of claim 1, wherein the stiffening body comprises a thickened region.

9. The optical module of claim 1, wherein the stiffening body comprises a stiffening rib.

10. The optical module of claim 1, further comprising sensor elements, wherein the stiffening body comprises a thickened region which is a reference region supporting the sensor elements.

11. The optical module of claim 1, wherein the optical element and/or the stiffening body comprise fluid channels.

12. The optical module of claim 1, wherein the optical element comprises a mirror.

13. The optical module of claim 1, wherein the Young's modulus of the material of the stiffening body is at least twice the Young's modulus of the material of the optical element

14. The optical module of claim 1, further comprising a passive decoupling element comprising a region which is deflectable parallel to an optical axis of the optical module, wherein the passive decoupling element is coupled to the actuator.

15. An apparatus, comprising:
an optical module according to claim 1,
wherein the apparatus comprises a semiconductor lithography projection exposure apparatus.

16. The apparatus of claim 15, further comprising:
an illumination optics unit; and
a projection optics unit,
wherein:
the illumination optics unit is configured to illuminate an object field in an object plane of the projection optics unit;
the projection optics unit is configured to image the illumination field into an object field in an object plane of the projection optics unit; and
the projection optics unit comprises the optical module.

17. An optical module, comprising:
an optical element comprising an optical effective surface;
a stiffening body comprising a ceramic;
an actuator connecting the optical element and the stiffening body,
wherein:
the actuator comprises a region mechanically decoupling the stiffening body and the optical element parallel to the optical effective surface; and
the region of the actuator is deflectable parallel to the optical effective surface.

18. The optical module of claim 17, wherein the stiffening body comprises silicon carbide.

19. An apparatus, comprising:
an optical module according to claim 17,
wherein the apparatus comprises a semiconductor lithography projection exposure apparatus.

20. The apparatus of claim 19, further comprising:
an illumination optics unit; and
a projection optics unit,
wherein:
the illumination optics unit is configured to illuminate an object field in an object plane of the projection optics unit;
the projection optics unit is configured to image the illumination field into an object field in an object plane of the projection optics unit; and
the projection optics unit comprises the optical module.
